(19) United States
(12) Patent Application Publication
(10) Pub. No.: US 2026/0194090 A1
(43) Pub. Date: Jul. 9, 2026

(54) FLAT-PLATE-MEMBER CLIP AND ATTACHMENT STRUCTURE OF FLAT-PLATE-MEMBER CLIP

(71) Applicant: ISUZU MOTORS LIMITED, Yokohama-shi (JP)

(72) Inventors: Yoshinori GOTO, Fujisawa-shi (JP); Yusuke HOSONO, Fujisawa-shi (JP); Hitoshi MIYAMAE, Yokohama-shi (JP); Tomoyuki MATSUMOTO, Yokohama-shi (JP)

(21) Appl. No.: 19/424,651

(22) Filed: Dec. 18, 2025

(30) Foreign Application Priority Data
Jan. 6, 2025 (JP) 2025-000110

(51) Int. Cl. F16B 5/06; F16B 2/22

(52) U.S. Cl. CPC F16B 5/0621; F16B 2/22

(57) ABSTRACT

A flat-plate-member clip can improve an efficiency of an operation of inserting a flat plate member and a clamping force for clamping the flat plate member. The flat-plate-member clip includes a first clamping plate including an elastic piece, a second clamping plate that clamps the flat plate member together with the first clamping plate, a coupling portion that couples the first clamping plate to the second clamping plate such that a first facing surface of the first clamping plate and a second facing surface of the second clamping plate face each other while being spaced apart from each other, and a locking section. The second clamping plate includes a recessed portion that includes a bottom surface that is formed to be recessed from the second facing surface. At least a part of a contact portion of the elastic piece is disposed to enter an inside of the recessed portion.

### CROSS REFERENCE TO RELATED APPLICATIONS

This application is entitled to (or claims) the benefit of Japanese Patent Application No.2025-000110 filed on January 6, 2025, the disclosure of which including the specification, drawings and abstract is incorporated herein by reference in its entirety.

### TECHNICAL FIELD

The present invention relates to a clip for a flat plate member (hereinafter, referred to as “flat-plate-member clip”) and an attachment structure of the flat-plate-member clip for fixing a flat plate member to an attachment target member.

### BACKGROUND ART

Patent Literature (hereinafter, referred to as “PTL”) 1 discloses a clip for fixing a flexible printed circuit to a support member. The clip disclosed in PTL 1 includes a first clamping plate, a second clamping plate, and a clip. The first clamping plate and the second clamping plate are disposed to face each other via the flexible printed circuit and clamp and fix the flexible printed circuit in a film thickness direction. A clip section is formed integrally with a clamping section to fix the first clamping plate and the second clamping plate to the support member.

A plurality of protrusions for preventing slipping are disposed on a facing surface of each of the first clamping plate and the second clamping plate disclosed in PTL 1 such that the flexible printed circuit clamped and fixed by the first clamping plate and the second

clamping plate can be favorably clamped and fixed. However, since the plurality of protrusions for preventing slipping are disposed on the facing surface of each of the first clamping plate and the second clamping plate, there is a problem that it is difficult to perform an operation of inserting the flexible printed circuit between the first clamping plate and the second clamping plate.

### Citation List

### Patent Literature

PTL 1

Japanese Patent Application Laid-Open No. 2002-204082

### SUMMARY OF INVENTION

### Technical Problem

The present invention has been made in view of the above circumstances, and an object thereof is to provide a flat-plate-member clip and an attachment structure of the flat-plate-member clip, which can improve an efficiency of an operation of inserting the flat plate member and a clamping force for clamping the flat plate member.

### Solution to Problem

A first aspect of the present invention is a flat-plate-member clip for fixing a flat plate member to an attachment target member, the flat-plate-member clip including: a first clamping plate including an elastic piece that is provided to be elastically deformable and that presses the flat plate member; a second clamping plate that extends in a predetermined direction and that, together with the first clamping plate, clamps the flat plate member; a coupling portion that couples together base end sides of the first clamping plate and the second clamping plate in the predetermined direction such that a first facing surface of the first clamping plate and a second facing surface of the second clamping plate face each other while being spaced apart from each other; and a locking section that is locked to the attachment target member, in which the second clamping plate includes a recessed portion that includes a bottom surface that is formed to be recessed from the second facing surface toward a side opposite to a side toward the first facing surface from the second facing surface, the elastic piece extends from the first facing surface toward the second facing surface while being inclined and extends toward the base end sides from a distal end side opposite to the base end sides in the predetermined direction, and at least a part of a contact portion that is provided at an end portion of the elastic piece on the base end sides and that makes contact with the flat plate member is disposed to enter an inside of the recessed portion.

According to the first aspect of the present invention, the first clamping plate includes an elastic piece that is provided to be elastically deformable and that presses the flat plate member. The second clamping plate extends in a predetermined direction and clamps the flat plate member together with the first clamping plate. In addition, the second clamping plate includes a recessed portion. The recessed portion of the second clamping plate includes a bottom surface that is formed to be recessed from the second facing surface toward a side opposite to a side toward the first facing surface of the first clamping plate from the second facing surface. Since the recessed portion includes the bottom surface, the flat plate member can be prevented from being caught in the recessed portion in a case where the flat plate member is inserted between the first clamping plate and the second clamping plate. As a result, the flat-plate-member clip according to the present invention can improve the efficiency of the operation of inserting the flat plate member.

In addition, the elastic piece of the first clamping plate extends from the first facing surface toward the second facing surface while being inclined and extends from the distal end side opposite to the base end side in the predetermined direction toward the base end side. Further, the elastic piece of the first clamping plate includes a contact portion that is provided at an end portion on a base end side and that makes contact with the flat plate member. At least a part of the contact portion is disposed to enter an inside of the recessed portion of the second clamping plate. As a result, the flat-plate-member clip according to the present invention can improve the clamping force for clamping the flat plate member.

A second aspect of the present invention is an attachment structure of a flat-plate-member clip, the attachment structure including: a flat plate member; an attachment target member to which the flat plate member is fixed; a plurality of first flat-plate-member clips for fixing the flat plate member to the attachment target member; and a second flat-plate-member clip for fixing the flat plate member to the attachment target member, in which each of the plurality of first flat-plate-member clips and the second flat-plate-member clip include: a first clamping plate including an elastic piece that is provided to be elastically deformable and that presses the flat plate member, a second clamping plate that extends in a predetermined direction and that, together with the first clamping plate, clamps the flat plate member, a coupling portion that couples together base end sides of the first clamping plate and the second clamping plate in the predetermined direction such that a first facing surface of the first clamping plate and a second facing surface of the second clamping plate face each other while being spaced apart from each other, and a locking section that is locked to the attachment target member, the second clamping plate includes a recessed portion that includes a bottom surface that is formed to be recessed from the second facing surface toward a side opposite to a side toward the first facing surface from the second facing surface, the elastic piece extends from the first facing surface toward the second facing surface while being inclined and extends toward the base end sides from a distal end side opposite to the base end sides in the predetermined direction, at least a part of a contact portion that is provided at an end portion of the elastic piece on the base end sides and that makes contact with the flat plate member is disposed to enter an inside of the recessed portion, a distal end of the first clamping plate of the first flat-plate-member clip is disposed at a position substantially the same as a distal end of the second clamping plate of the first flat-plate-member clip in the predetermined direction, a distal end of the first clamping plate of the second flat-plate-member clip is disposed between a distal end and a base end of the second clamping plate of the second flat-plate-member clip in the predetermined direction, and the second flat-plate-member clip is disposed between the plurality of first flat-plate-member clips in an extending direction of the flat plate member.

According to the second aspect of the present invention, the distal end of the first clamping plate of the first flat-plate-member clip is disposed at a position substantially the same as the distal end of the second clamping plate of the first flat-plate-member clip in the predetermined direction. The distal end of the first clamping plate of the second flat-plate-member clip is disposed between the distal end and the base end of the second clamping plate of the second flat-plate-member clip in the predetermined direction. The second flat-plate-member clip is disposed between the plurality of first flat-plate-member clips in the extending direction of the flat plate member. Therefore, in a case where the plurality of first flat-plate-member clips are disposed in the extending direction of the flat plate member to clamp the flat plate member, an operator or the like can easily perform the operation of inserting the flat plate member between the first clamping plate and the second clamping plate by using the second flat-plate-member clip disposed between the plurality of first flat-plate-member clips. As a result, the attachment structure of the flat-plate-member clip according to the present invention can improve the efficiency of the operation of inserting the flat plate member. In addition, by disposing at least a part of the contact portion of the elastic piece to enter the inside of the recessed portion of the second clamping plate, the attachment structure of the flat-plate-member clip according to the present invention can improve the clamping force for clamping the flat plate member.

### Advantageous Effects of Invention

According to the present invention, it is possible to provide a flat-plate-member clip and an attachment structure of the flat-plate-member clip, which can improve the efficiency of the operation of inserting the flat plate member and the clamping force for clamping the flat plate member.

### BRIEF DESCRIPTION OF DRAWINGS

FIG. 1 is a perspective view showing a state before a flat-plate-member clip according to the present embodiment is assembled to an attachment target member;

FIG. 2 is a perspective view showing a state after the flat-plate-member clip according to the present embodiment is assembled to the attachment target member;

FIG. 3 is a perspective view showing a state where the flat plate member is fixed to the attachment target member via the flat-plate-member clip according to the present embodiment;

FIG. 4 is a perspective view showing the flat-plate-member clip according to the present embodiment;

FIG. 5 is a plan view of the flat-plate-member clip according to the present embodiment as viewed in a direction of arrow A33 shown in FIG. 4;

FIG. 6 is an enlarged view of region A35 shown in FIG. 5;

FIG. 7 is a sectional view taken along a sectional plane A7-A7 shown in FIG. 5;

FIG. 8 is a perspective view showing an attachment structure of the flat-plate-member clip according to the present embodiment;

FIG. 9 is a perspective view showing a flat-plate-member clip according to another embodiment; and

FIG. 10 is a plan view of the flat-plate-member clip according to the other embodiment as viewed in a direction of arrow A34 shown in FIG. 9.

### DESCRIPTION OF EMBODIMENTS

Hereinafter, an embodiment of the present invention will be described with reference to the drawings.

The embodiment described below is a suitable specific example of the present invention, and thus various technically preferable limitations are applied. However, the scope of the present invention is not limited to these aspects unless otherwise specified in the following description. In addition, in each figure, the same components are designated by the same reference numerals, and detailed descriptions thereof will be omitted as appropriate.

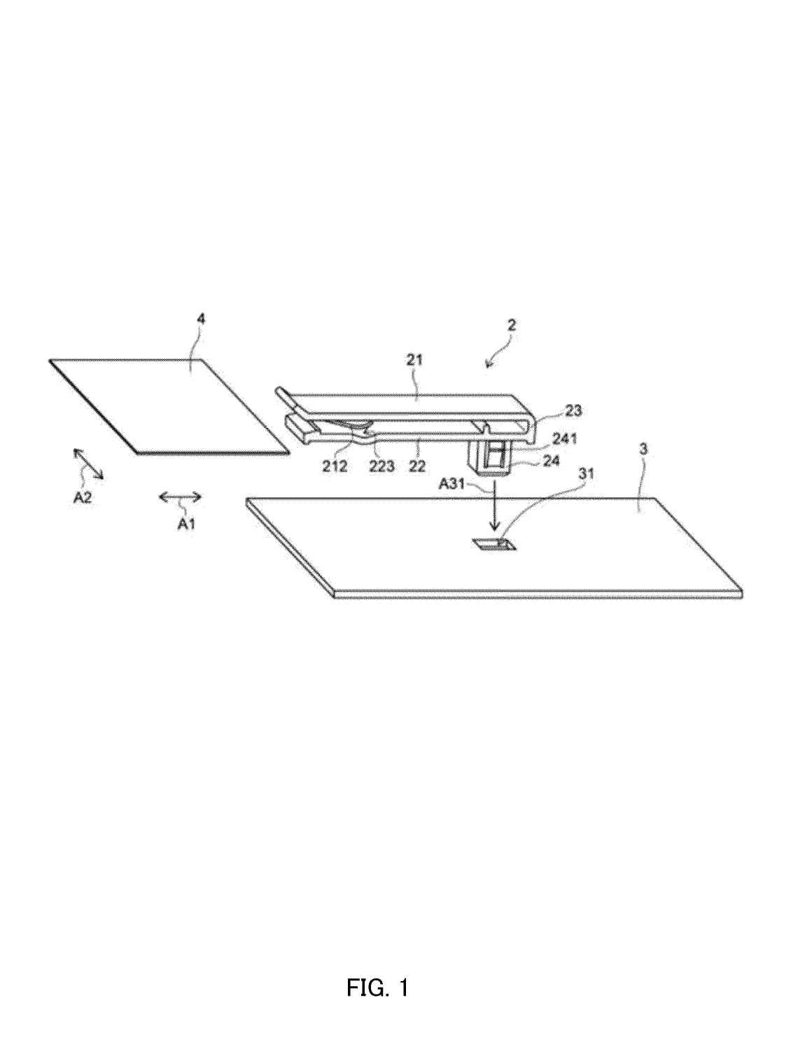

FIG. 1 is a perspective view showing a state before a flat-plate-member clip according to the present embodiment is assembled to an attachment target member.

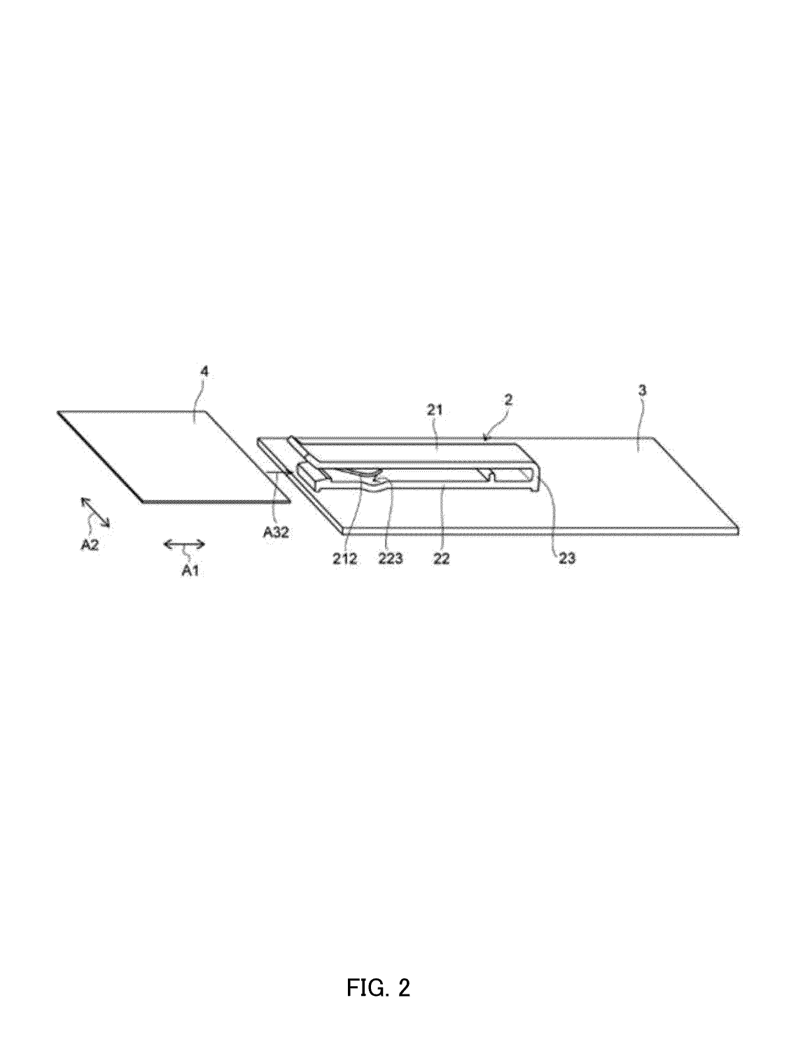

FIG. 2 is a perspective view showing a state after the flat-plate-member clip according to the present embodiment is assembled to the attachment target member.

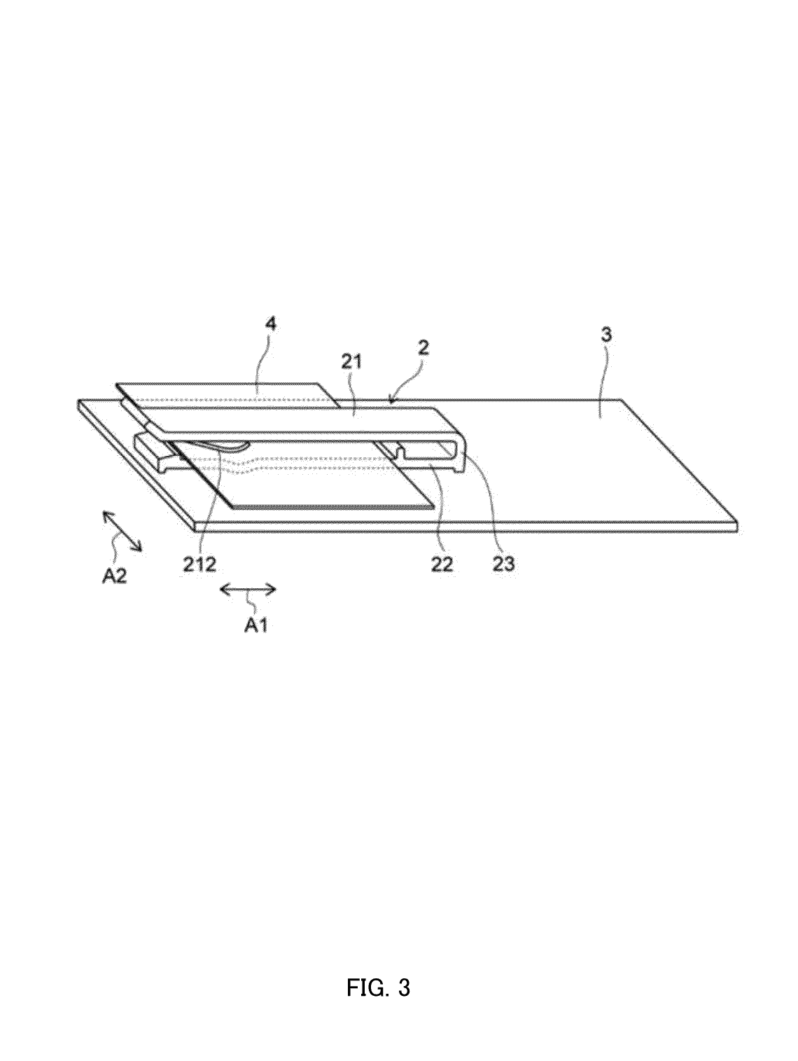

FIG. 3 is a perspective view showing a state where the flat plate member is fixed to the attachment target member via the flat-plate-member clip according to the present embodiment.

As shown in FIGS. 1 to 3, flat-plate-member clip 2 according to the present embodiment is used to fix flat plate member 4 to attachment target member 3. That is, flat plate member 4 is mounted or held by flat-plate-member clip 2 and is fixed to attachment target member 3 via flat-plate-member clip 2.

Examples of flat plate member 4 include flexible printed circuits (FPCs) and flexible flat cables (FFCs). The flexible printed circuits are a wiring board formed by etching a conductor such as a copper foil provided on a resin film in accordance with a wiring pattern and covering the conductor with an insulating film. The flexible flat cables are a wiring material formed by arranging a plurality of rectangular conductors at regular intervals in a flat shape and sandwiching the conductors with an insulating film. However, flat plate member 4 is not limited to the flexible printed circuits and the flexible flat cables.

Examples of attachment target member 3 include a vehicle body panel. As shown in FIG. 1, attachment target member 3 includes through-hole 31. Through-hole 31 penetrates attachment target member 3 in a plate thickness direction.

As shown in FIG. 1, flat-plate-member clip 2 includes first clamping plate 21, second clamping plate 22, coupling portion 23, and locking section 24. First clamping plate 21 and second clamping plate 22 are coupled to each other by coupling portion 23 on a base end side in first direction A1 and are spaced from each other on a distal end side in first direction A1. First direction A1 of the present embodiment is an example of a “predetermined direction” of the present invention and corresponds to a width direction of flat plate member 4. In addition, second direction A2 shown in FIGS. 1 to 3 is a direction orthogonal to first direction A1, corresponds to an extending direction (that is, a longitudinal direction) of flat plate member 4, and corresponds to a width direction of first clamping plate 21 and second clamping plate 22. A detailed structure of first clamping plate 21 and second clamping plate 22 will be described below.

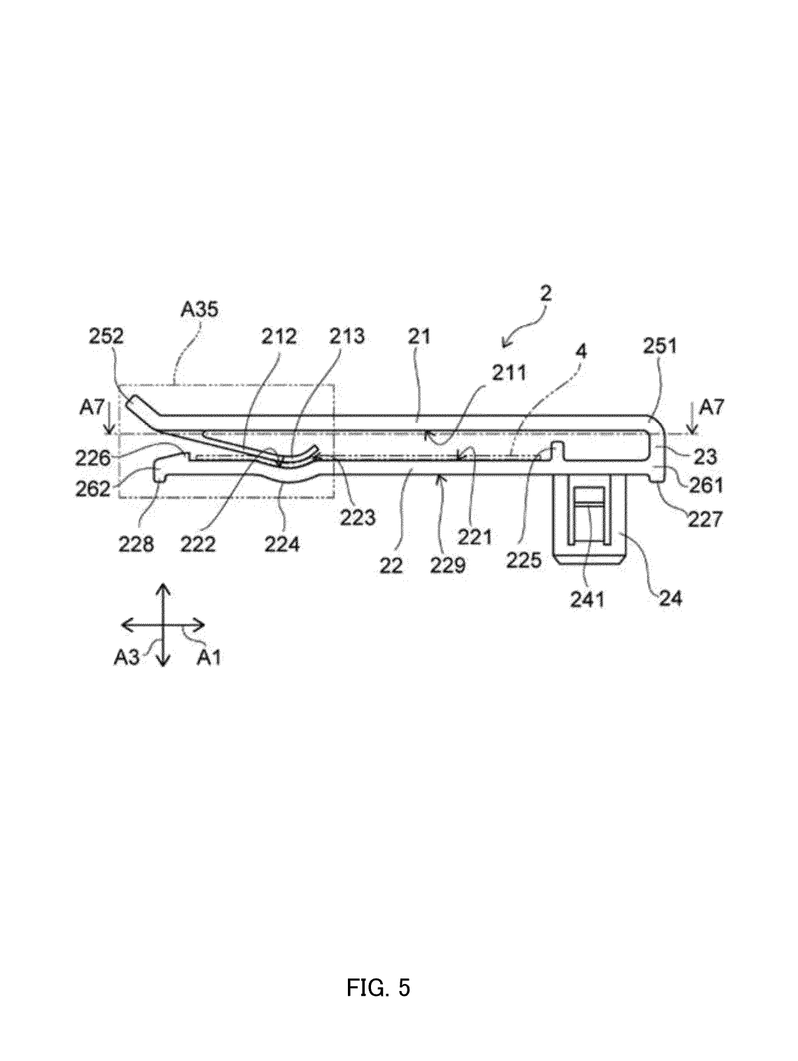

Locking section 24 is attached to outer surface 229 (see FIG. 5) of second clamping plate 22 and includes projecting portion 241. Projecting portion 241 protrudes outward from locking section 24 and is formed to be elastically deformable in second direction A2. Locking section 24 is not limited to being attached to outer surface 229 of second clamping plate 22, and may be attached to, for example, an outer surface of coupling portion 23.

As shown by arrow A31 shown in FIG. 1, in a case where locking section 24 is inserted into through-hole 31 of attachment target member 3, a distal end of projecting portion 241 comes into contact with an inner surface of through-hole 31. In a case where locking section 24 is further inserted into through-hole 31 of attachment target member 3, projecting portion 241 is elastically deformed, and the distal end of projecting portion 241 moves in a direction of arrow A31 shown in FIG. 1 while coming into contact with the inner surface of through-hole 31. Then, projecting portion 241 passes beyond attachment target member 3 and comes into contact with an edge on a back side (lower side in FIG. 1) of through-hole 31. As a result, locking section 24 is fitted into through-hole 31 of attachment target member 3 and is locked to attachment target member 3. Accordingly, second clamping plate 22 is disposed to face attachment target member 3.

As shown by arrow A32 shown in FIG. 2, in a case where flat plate member 4 is inserted between first clamping plate 21 and second clamping plate 22 from the distal end side toward the base end side in first direction A1, flat plate member 4 is clamped by first clamping plate 21 and second clamping plate 22. That is, as shown in FIG. 3, first clamping plate 21 and second clamping plate 22 hold flat plate member 4 by clamping flat plate member 4 between them. In this manner, flat plate member 4 is fixed to attachment target member 3 via flat-plate-member clip 2.

Next, a detailed structure of flat-plate-member clip 2 according to the present embodiment will be described with reference to the drawings.

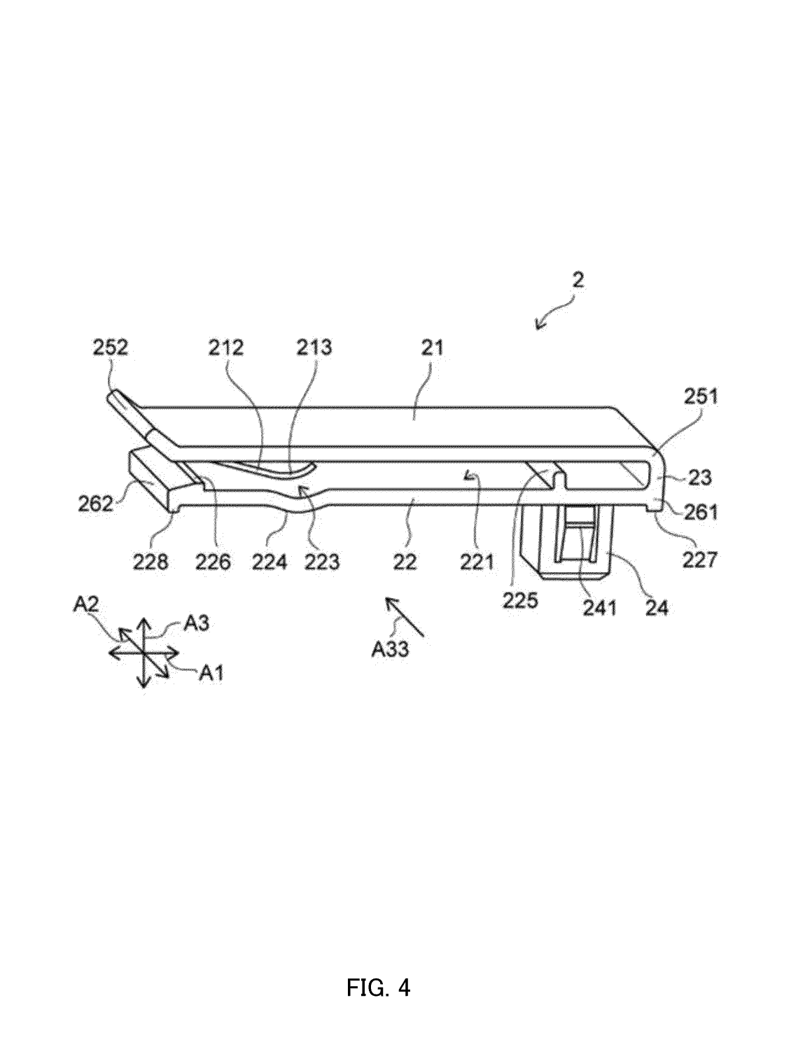

FIG. 4 is a perspective view showing the flat-plate-member clip according to the present embodiment.

FIG. 5 is a plan view of the flat-plate-member clip according to the present embodiment as viewed in a direction of arrow A33 shown in FIG. 4.

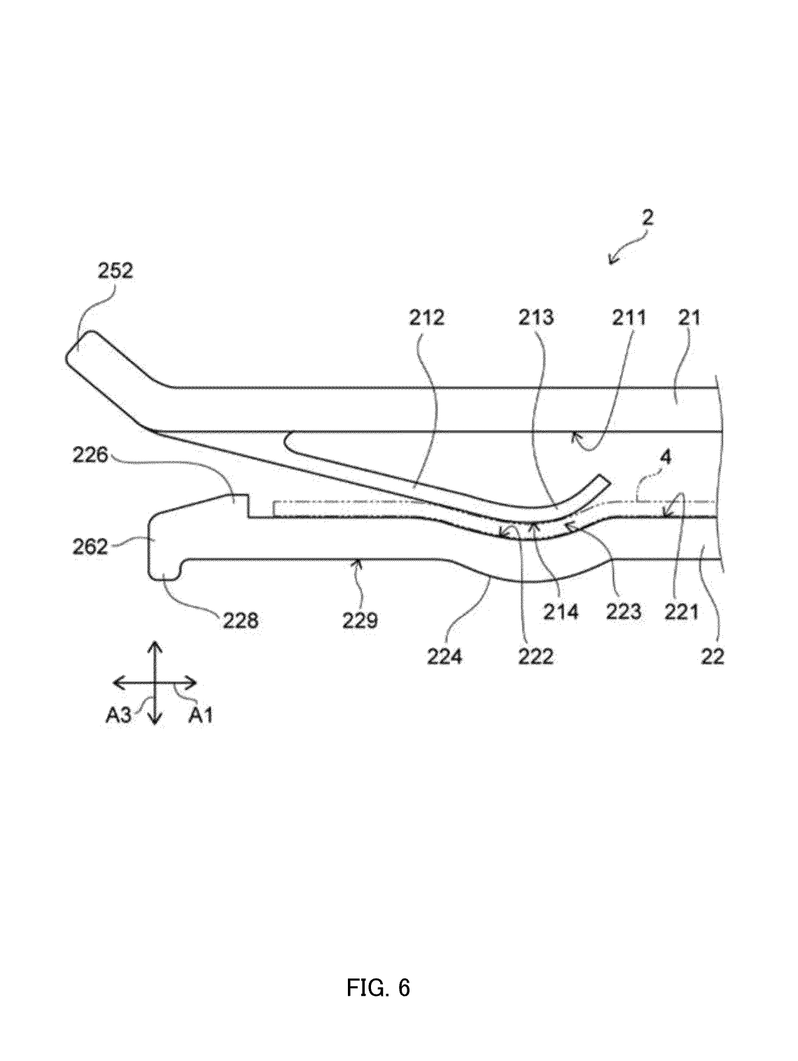

FIG. 6 is an enlarged view of region A35 shown in FIG. 5.

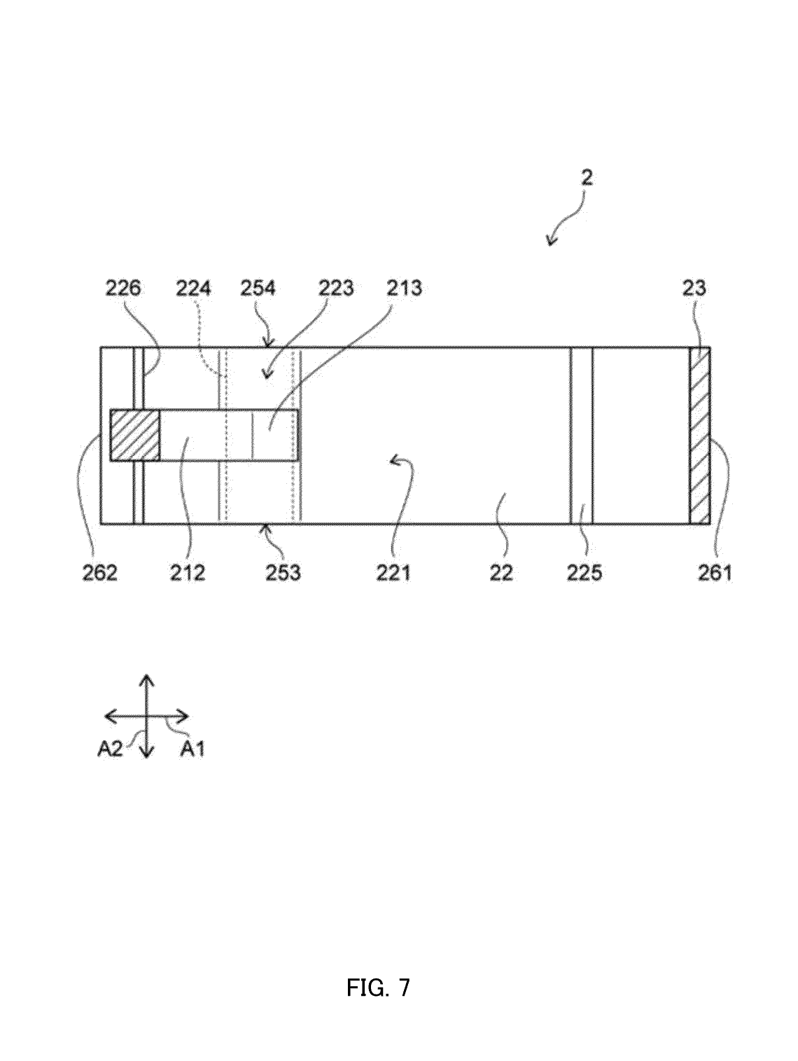

FIG. 7 is a sectional view taken along a sectional plane A7-A7 shown in FIG. 5.

Flat-plate-member clip 2 includes first clamping plate 21, second clamping plate 22, coupling portion 23, and locking section 24. As shown in FIGS. 4 and 5, coupling portion 23 couples together the base end sides of first clamping plate 21 and second clamping plate 22 such that first facing surface 211 of first clamping plate 21 and second facing surface 221 of second clamping plate 22 face each other while being spaced apart from each other. Specifically, coupling portion 23 couples base end 251 of first clamping plate 21 in first direction A1 and base end 261 of second clamping plate 22 in first direction A1 to each other.

On the other hand, as shown in FIGS. 5 and 6, distal end 252 of first clamping plate 21 in first direction A1 and distal end 262 of second clamping plate 22 in first direction A1 are spaced from each other. That is, an opening is defined between distal end 252 of first clamping plate 21 in first direction A1 and distal end 262 of second clamping plate 22 in first direction A1. As described above with respect to FIG. 2, flat plate member 4 is inserted between first clamping plate 21 and second clamping plate 22 by passing through the opening defined between distal end 252 of first clamping plate 21 and distal end 262 of second clamping plate 22 and is clamped by first clamping plate 21 and second clamping plate 22 (see arrow A32 in FIG. 2).

Locking section 24 is as described above with respect to FIGS. 1 to 3.

First clamping plate 21 extends in first direction A1. A length of first clamping plate 21 in first direction A1 is substantially the same as a length of second clamping plate 22 in first direction A1. That is, in first direction A1, a position of distal end 252 of first clamping plate 21 is substantially the same as a position of distal end 262 of second clamping plate 22.

First clamping plate 21 includes elastic piece 212. Elastic piece 212 is provided to be elastically deformable and has a function of pressing flat plate member 4 as shown in FIG. 6. As shown in FIGS. 5 and 6, elastic piece 212 extends from first facing surface 211 toward second facing surface 221 while being inclined and extends from a distal end side toward a base end side in first direction A1.

As shown in FIG. 6, elastic piece 212 of the present embodiment extends from first facing surface 211 of first clamping plate 21 at distal end 252 toward second facing surface 221 while being inclined. Elastic piece 212 may extend from first facing surface 211 at an intermediate portion between distal end 252 and base end 251 of first clamping plate 21 toward second facing surface 221 while being inclined.

Elastic piece 212 includes contact portion 213. As shown in FIG. 6, contact portion 213 is provided at an end portion of elastic piece 212 on the base end side and is formed to be curved in a substantially arc shape when viewed in second direction A2. Contact portion 213 comes into contact with flat plate member 4 in a case where flat plate member 4 is clamped between first clamping plate 21 and second clamping plate 22. That is, elastic piece 212 is elastically deformed by coming into contact with flat plate member 4 at contact portion 213 to press flat plate member 4. In addition, since contact portion 213, which is an end portion of elastic piece 212, has an arc shape, it is possible to prevent flat plate member 4 from being caught on an end of contact portion 213 when the operator or the like removes flat plate member 4 from flat-plate-member clip 2.

Second clamping plate 22 extends in first direction A1 and clamps flat plate member 4 together with first clamping plate 21. A length of second clamping plate 22 in first direction A1 is substantially the same as a length of first clamping plate 21 in first direction A1. This is as described above with respect to first clamping plate 21.

Second clamping plate 22 includes recessed portion 223. As shown in FIGS. 5 and 6, recessed portion 223 includes bottom surface 222. That is, recessed portion 223 is a space having a bottom. Bottom surface 222 is formed to be recessed from second facing surface 221 toward a side opposite to a side toward first facing surface 211 from second facing surface 221. Specifically, when viewed in second direction A2, bottom surface 222 is formed to be curved in a substantially arc shape to maintain a predetermined gap relative to contact portion 213 along a surface (lower surface in FIGS. 5 and 6) of contact portion 213 of elastic piece 212. That is, bottom surface 222 is formed to be substantially parallel to the surface of contact portion 213 of elastic piece 212. As a result, in a case where contact portion 213 and bottom surface 222 clamp flat plate member 4, a strong force is not locally applied to flat plate member 4, and a force can be stably applied to flat plate member 4 within a range where contact portion 213 makes contact with flat plate member 4.

As shown in FIG. 7, recessed portion 223 extends between first end portion 253 of second clamping plate 22 in second direction A2 and second end portion 254 of second clamping plate 22 in second direction A2. That is, recessed portion 223 extends between the opposite lateral ends of second clamping plate 22 in second direction A2. The opposite lateral ends of recessed portion 223 in second direction A2 are open. That is, recessed portion 223 is open from first end portion 253 of second clamping plate 22 toward the outside of second clamping plate 22 and is open from second end portion 254 of second clamping plate 22 toward the outside of second clamping plate 22.

As shown in FIGS. 5 and 6, second clamping plate 22 includes protruding portion 224. Protruding portion 224 protrudes from outer surface 229 of second clamping plate 22 toward the outside. Specifically, protruding portion 224 is formed to be curved in a substantially arc shape when viewed in second direction A2, so as to follow bottom surface 222 of recessed portion 223. As a result, a thickness of second clamping plate 22 is maintained substantially constant. Outer surface 229 of second clamping plate 22 faces a surface of attachment target member 3 in a case where locking section 24 is attached to outer surface 229.

As shown in FIG. 7, protruding portion 224 is disposed to overlap recessed portion 223 when viewed in third direction A3 (see FIGS. 4 to 6). Third direction A3 is a direction orthogonal to first direction A1 and second direction A2 and corresponds to a direction (that is, a facing direction) in which first facing surface 211 of first clamping plate 21 and second facing surface 221 of second clamping plate 22 face each other.

Second clamping plate 22 further includes first leg portion 227 and second leg portion 228. First leg portion 227 protrudes outward from outer surface 229 of second clamping plate 22 at base end 261 of second clamping plate 22. Second leg portion 228 protrudes outward from outer surface 229 of second clamping plate 22 at distal end 262 of second clamping plate 22.

A height from outer surface 229 to the distal end of first leg portion 227, a height from outer surface 229 to the distal end of second leg portion 228, and a height from outer surface 229 to the distal end (that is, a top) of protruding portion 224 are the same as each other. Therefore, flat-plate-member clip 2 is stably placed on the surface of attachment target member 3 and is supported by attachment target member 3 at first leg portion 227, second leg portion 228, and protruding portion 224.

Second clamping plate 22 further includes first stopper portion 225 and second stopper portion 226. First stopper portion 225 is provided on the base end 261 side with respect to a middle portion (that is, an intermediate portion between base end 261 and distal end 262) of second clamping plate 22 in first direction A1 and protrudes from second facing surface 221 toward first facing surface 211. Second stopper portion 226 is provided on the distal end 262 side with respect to the middle portion of second clamping plate 22 in first direction A1 and protrudes from second facing surface 221 toward first facing surface 211. As shown in FIG. 6, second stopper portion 226 of the present embodiment is provided on distal end 262 side with respect to recessed portion 223, and is specifically provided in the vicinity of distal end 262 of second clamping plate 22. Second stopper portion 226 of the present embodiment is an example of a “protrusion” of the present invention.

As shown in FIG. 5, flat plate member 4 is placed on second facing surface 221 between first stopper portion 225 and second stopper portion 226. First stopper portion 225 prevents flat plate member 4 clamped between first clamping plate 21 and second clamping plate 22 from moving toward base end 261 of second clamping plate 22. Second stopper portion 226 prevents flat plate member 4 clamped between first clamping plate 21 and second clamping plate 22 from being pulled out from the opening between distal end 252 of first clamping plate 21 and distal end 262 of second clamping plate 22. Since flat plate member 4 is pressed in a direction from first facing surface 211 toward second facing surface 221 by elastic piece 212, flat plate member 4 clamped between first clamping plate 21 and second clamping plate 22 can be effectively prevented from being pulled out from the opening by providing second stopper portion 226 on second facing surface 221.

In flat-plate-member clip 2 shown in FIGS. 4 to 7, recessed portion 223 is formed on the distal end 262 side with respect to the middle portion (that is, an intermediate portion between base end 261 and distal end 262) of second clamping plate 22 in first direction A1. However, recessed portion 223 may be formed in the intermediate portion between first stopper portion 225 and second stopper portion 226 in first direction A1. In this case, contact portion 213 of elastic piece 212 is disposed at a position corresponding to recessed portion 223, that is, at the intermediate portion between first stopper portion 225 and second stopper portion 226 in first direction A1.

As shown in FIG. 6, elastic piece 212 extends from first facing surface 211 toward second facing surface 221 while being inclined and enters the inside of recessed portion 223 beyond second facing surface 221. In addition, at least a part of contact portion 213 of elastic piece 212 is disposed to enter the inside of recessed portion 223. The “at least a part of contact portion 213” referred to herein includes top 214 of contact portion 213 that is formed in a substantially arc shape. A portion of contact portion 213 from top 214 to the base end side extends from first facing surface 211 while being inclined and is disposed outside recessed portion 223.

As described above, according to flat-plate-member clip 2 according to the present embodiment, recessed portion 223 of second clamping plate 22 includes bottom surface 222. Therefore, in a case where flat plate member 4 is inserted between first clamping plate 21 and second clamping plate 22 and passes through the gap between contact portion 213 of elastic piece 212 and bottom surface 222 of recessed portion 223, flat plate member 4 can be smoothly inserted between first clamping plate 21 and second clamping plate 22 by preventing flat plate member 4 from being caught in recessed portion 223. As a result, flat-plate-member clip 2 according to the present embodiment can improve the efficiency of the operation of inserting flat plate member 4.

In addition, elastic piece 212 extends from first facing surface 211 toward second facing surface 221 while being inclined and extends from the distal end side toward the base end side in first direction A1. Further, at least a part of contact portion 213 is disposed to enter the inside of recessed portion 223. As a result, flat-plate-member clip 2 according to the present embodiment can improve the clamping force for clamping flat plate member 4.

In addition, recessed portion 223 of second clamping plate 22 extends between the opposite lateral ends of second clamping plate 22 in second direction A2. The opposite lateral ends of recessed portion 223 in second direction A2 are open. Therefore, in a case where flat plate member 4 is inserted between the first clamping plate and the second clamping plate and passes through the gap between contact portion 213 of elastic piece 212 and bottom surface 222 of recessed portion 223, the followability of flat plate member 4 to recessed portion 223 is improved as compared with a case where the opposite lateral ends of recessed portion 223 in second direction A2 are closed. As a result, flat-plate-member clip 2 according to the present embodiment can further improve the efficiency of the operation of inserting flat plate member 4.

In addition, protruding portion 224 of second clamping plate 22 is disposed to overlap recessed portion 223 when viewed in third direction A3. Therefore, second clamping plate 22 is supported by attachment target member 3 by protruding portion 224 in a region where first clamping plate 21 and second clamping plate 22 clamp flat plate member 4. As a result, flat-plate-member clip 2 according to the present embodiment can suppress flat plate member 4 from flapping and can stably hold flat plate member 4. In addition, the plate thickness of second clamping plate 22 can be uniformly set, and the efficiency of manufacturing flat-plate-member clip 2 according to the present embodiment can be improved.

Further, recessed portion 223 of second clamping plate 22 is formed on the distal end 262 side with respect to the middle portion of second clamping plate 22 in first direction A1. Contact portion 213 of elastic piece 212 is formed at a position corresponding to recessed portion 223, that is, on the distal end 252 side with respect to the middle portion of first clamping plate 21 in first direction A1. Therefore, elastic piece 212 can press flat plate member 4 in the vicinity of distal end 252 of first clamping plate 21 and distal end 262 of second clamping plate 22. As a result, flat-plate-member clip 2 according to the present embodiment can more reliably prevent flat plate member 4 from being pulled out from the opening between distal end 252 of first clamping plate 21 and distal end 262 of second clamping plate 22 while suppressing flat plate member 4 from flapping.

Next, an attachment structure of the flat-plate-member clip according to the present embodiment will be described with reference to the drawings.

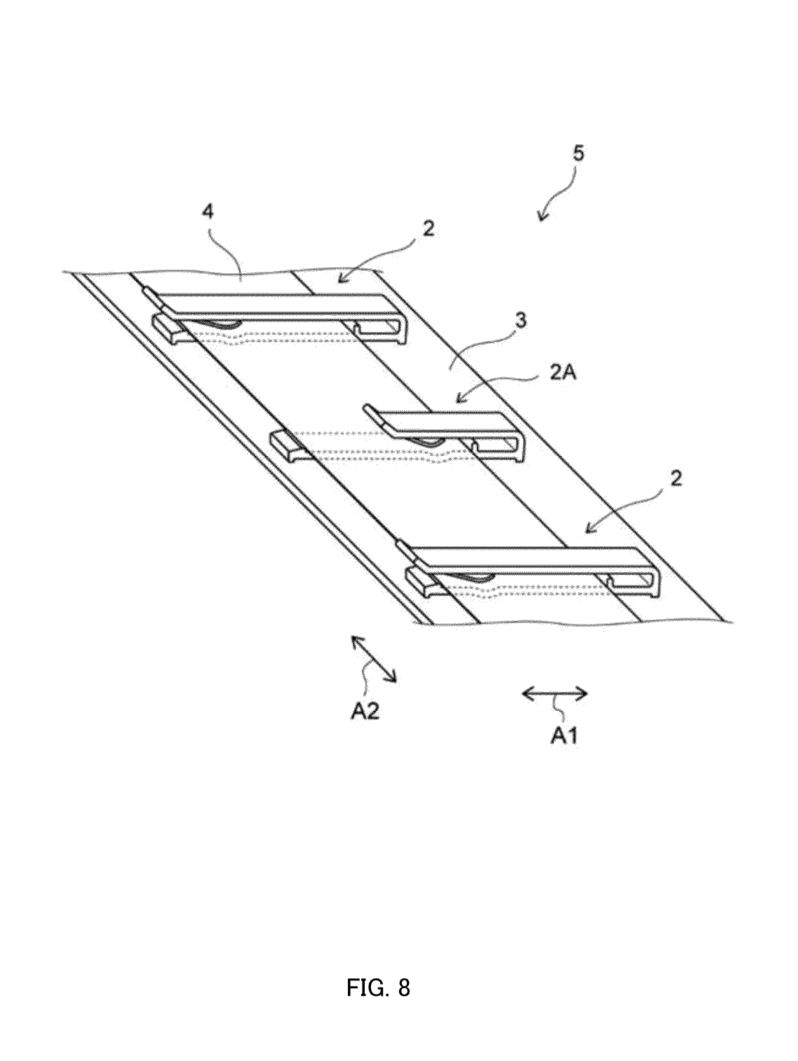

FIG. 8 is a perspective view showing the attachment structure of the flat-plate-member clip according to the present embodiment.

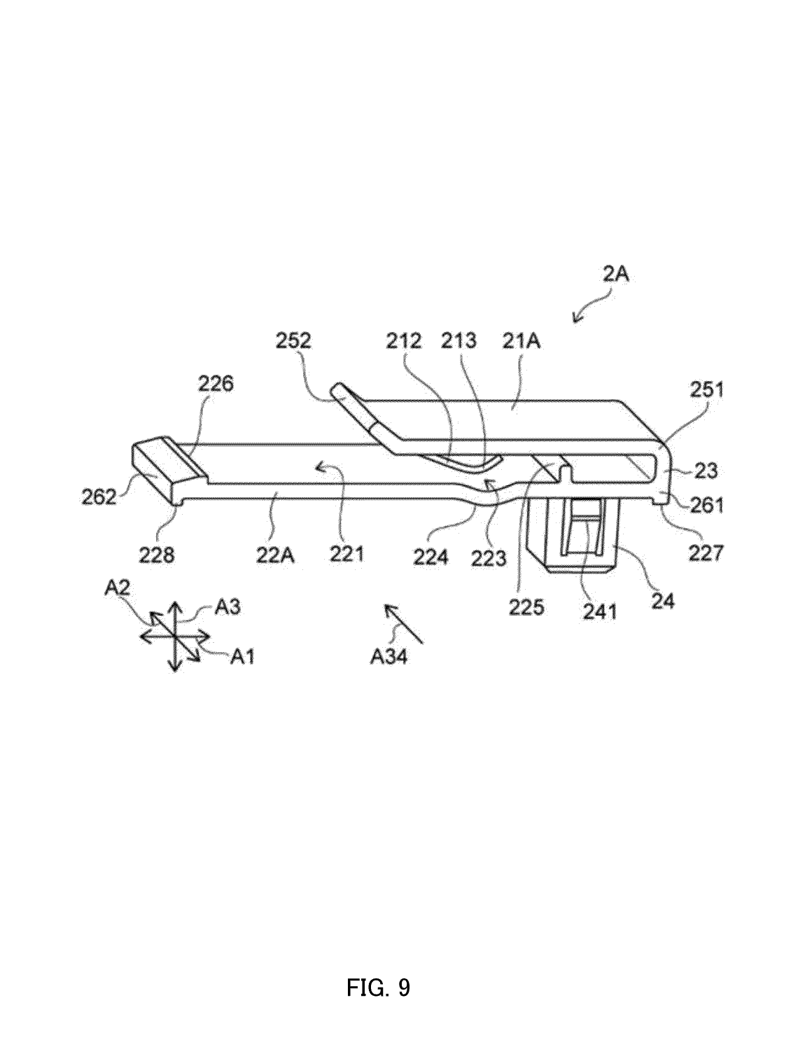

FIG. 9 is a perspective view showing a flat-plate-member clip according to another embodiment.

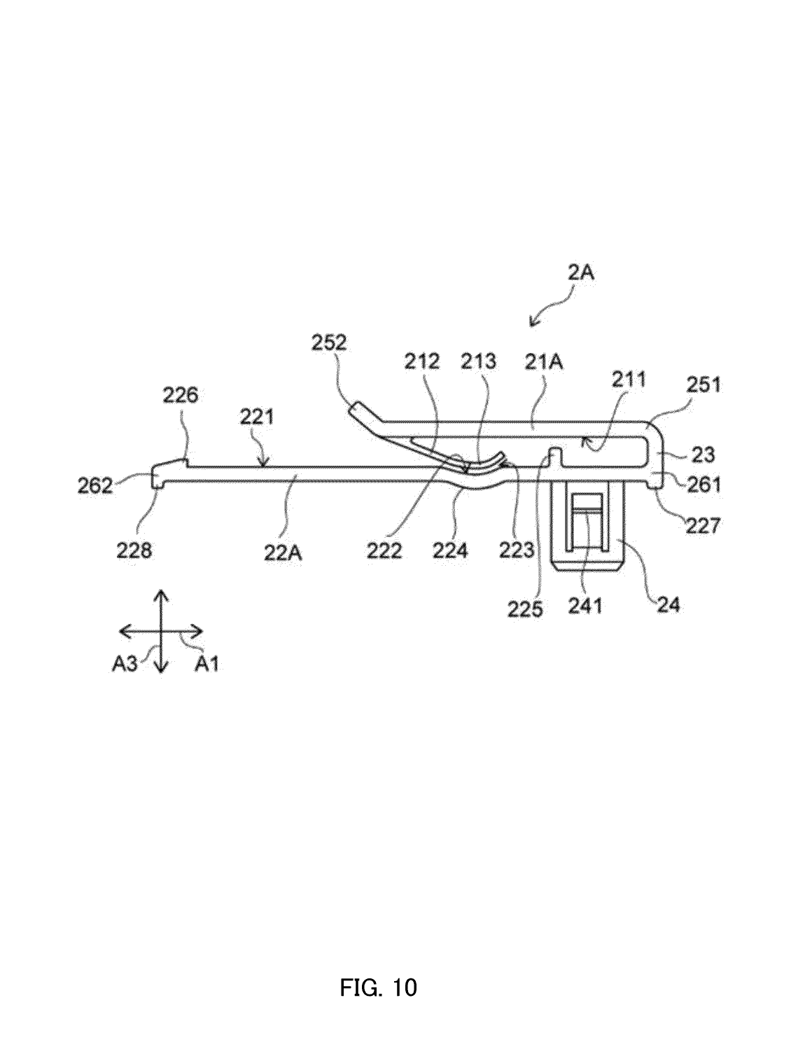

FIG. 10 is a plan view of the flat-plate-member clip according to the other embodiment as viewed in a direction of arrow A34 shown in FIG. 9.

In the following description, for convenience of description, flat-plate-member clip 2 according to the embodiment described above with respect to FIGS. 1 to 7 will be referred to as a “first flat-plate-member clip.” In addition, flat-plate-member clip 2A according to the other embodiment will be referred to as a “second flat-plate-member clip.”

In a case where the components of second flat-plate-member clip 2A are the same as the components of first flat-plate-member clip 2, overlapping descriptions will be omitted as appropriate, and the differences will be mainly described below.

First, a structure of second flat-plate-member clip 2A will be described.

As shown in FIGS. 9 and 10, second flat-plate-member clip 2A includes first clamping plate 21A, second clamping plate 22A, coupling portion 23, and locking section 24.

First clamping plate 21A extends in first direction A1. A length of first clamping plate 21A in first direction A1 is shorter than a length of second clamping plate 22A in first direction A1. In first direction A1, distal end 252 of first clamping plate 21A is disposed between base end 261 and distal end 262 of second clamping plate 22A. Specifically, in first direction A1, distal end 252 of first clamping plate 21A is disposed at a middle portion (that is, an intermediate portion between base end 261 and distal end 262) of second clamping plate 22A.

Second clamping plate 22A extends in first direction A1 and clamps flat plate member 4 together with first clamping plate 21A. The length of second clamping plate 22A in first direction A1 is longer than the length of first clamping plate 21A in first direction A1.

As shown in FIG. 10, recessed portion 223 of second clamping plate 22A is formed on the base end 261 side with respect to the middle portion of second clamping plate 22A in first direction A1. Specifically, recessed portion 223 of second clamping plate 22A is formed in the vicinity of first stopper portion 225.

Contact portion 213 of elastic piece 212 is disposed at a position corresponding to recessed portion 223, that is, on the base end 261 side (specifically, in the vicinity of first stopper portion 225) with respect to the middle portion of second clamping plate 22A in first direction A1. Therefore, elastic piece 212 can press flat plate member 4 in the vicinity of first stopper portion 225.

The other structures are the same as the structures of first flat-plate-member clip 2 described above with respect to FIGS. 1 to 7.

Subsequently, attachment structure 5 of the flat-plate-member clip according to the present embodiment will be described.

As shown in FIG. 8, attachment structure 5 of the flat-plate-member clip according to the present embodiment includes first flat-plate-member clips 2, second flat-plate-member clip 2A, attachment target member 3, and flat plate member 4. First flat-plate-member clips 2 and second flat-plate-member clip 2A are disposed side by side in second direction A2 (that is, the extending direction of flat plate member 4).

Second flat-plate-member clip 2A is disposed between the plurality of first flat-plate-member clips 2 in second direction A2. In the example shown in FIG. 8, one second flat-plate-member clip 2A is disposed between two first flat-plate-member clips 2. However, the arrangement of first flat-plate-member clips 2 and second flat-plate-member clip 2A is not limited thereto.

For example, two or more second flat-plate-member clips 2A may be disposed between two first flat-plate-member clips 2. Alternatively, for example, first flat-plate-member clips 2 and second flat-plate-member clips 2A may be alternately disposed in second direction A2. The attachment structure of the flat-plate-member clip is included in attachment structure 5 of the flat-plate-member clip according to the present embodiment as long as second flat-plate-member clip 2A is disposed between the plurality of first flat-plate-member clips 2 in second direction A2.

According to attachment structure 5 of the flat-plate-member clips according to the present embodiment, in a case where the plurality of first flat-plate-member clips 2 are disposed in the extending direction of flat plate member 4 to clamp flat plate member 4, the operator or the like can easily perform the operation of inserting flat plate member 4 between first clamping plates 21 and second clamping plates 22 and between first clamping plate 21A and second clamping plate 22A by using second flat-plate-member clip 2A disposed between the plurality of first flat-plate-member clips 2. As a result, attachment structure 5 of the flat-plate-member clip according to the present embodiment can improve the efficiency of the operation of inserting flat plate member 4.

In addition, by disposing at least a part of contact portion 213 of elastic piece 212 to enter the inside of recessed portion 223 of each of second clamping plate 22 and second clamping plate 22A, attachment structure 5 of the flat-plate-member clip according to the present embodiment can improve the clamping force for clamping flat plate member 4.

The embodiment of the present invention has been described above. However, the present invention is not limited to the above-described embodiment, and various modifications can be made within the scope of the claims. The configuration of the above-described embodiment can be modified by omitting a part thereof or arbitrarily combining the components in a manner different from the above-described embodiment.

### Reference Signs List

2 Flat-plate-member clip (first flat-plate-member clip)

2A Flat-plate-member clip (second flat-plate-member clip)

3 Attachment target member

4 Flat plate member

5 Attachment structure

21 First clamping plate

21A First clamping plate

22 Second clamping plate

22A Second clamping plate

23 Coupling portion

24 Locking section

31 Through-hole

211 First facing surface

212 Elastic piece

213 Contact portion

214 Top

221 Second facing surface

222 Bottom surface

223 Recessed portion

224 Protruding portion

225 First stopper portion

226 Second stopper portion

227 First leg portion

228 Second leg portion

229 Outer surface

241 Projecting portion

251 Base end

252 Distal end

253 First end portion

254 Second end portion

261 Base end

262 Distal end

1. A flat-plate-member clip for fixing a flat plate member to an attachment target member, the flat-plate-member clip comprising:
a first clamping plate including an elastic piece that is provided to be elastically deformable and that presses the flat plate member;
a second clamping plate that extends in a predetermined direction and that, together with the first clamping plate, clamps the flat plate member;
a coupling portion that couples together base end sides of the first clamping plate and the second clamping plate in the predetermined direction such that a first facing surface of the first clamping plate and a second facing surface of the second clamping plate face each other while being spaced apart from each other; and
a locking section that is locked to the attachment target member, wherein
the second clamping plate includes a recessed portion that includes a bottom surface that is formed to be recessed from the second facing surface toward a side opposite to a side toward the first facing surface from the second facing surface,
the elastic piece extends from the first facing surface toward the second facing surface while being inclined and extends toward the base end sides from a distal end side opposite to the base end sides in the predetermined direction, and
at least a part of a contact portion that is provided at an end portion of the elastic piece on the base end sides and that makes contact with the flat plate member is disposed to enter an inside of the recessed portion.

2. The flat-plate-member clip according to claim 1, wherein:
the recessed portion extends between opposite lateral ends of the second clamping plate in a width direction, and
opposite lateral ends of the recessed portion in the width direction are open.

3. The flat-plate-member clip according to claim 1, wherein:
the second clamping plate is disposed to face the attachment target member and includes a protruding portion that protrudes outward from an outer surface facing the attachment target member,
the locking section is attached to the outer surface, and
the protruding portion is disposed to overlap the recessed portion when viewed in a facing direction in which the first facing surface and the second facing surface face each other.

4. The flat-plate-member clip according to claim 1, wherein
the contact portion has a shape curved in an arc shape.

5. The flat-plate-member clip according to claim 4, wherein
the bottom surface is curved to maintain a predetermined gap relative to the contact portion.

6. The flat-plate-member clip according to claim 1, wherein
the second clamping plate includes a protrusion that is provided on the distal end side with respect to the recessed portion and that protrudes from the second facing surface toward the first facing surface from the second facing surface.

7. An attachment structure of a flat-plate-member clip, the attachment structure comprising:
a flat plate member;
an attachment target member to which the flat plate member is fixed;
a plurality of first flat-plate-member clips for fixing the flat plate member to the attachment target member; and
a second flat-plate-member clip for fixing the flat plate member to the attachment target member, wherein
each of the plurality of first flat-plate-member clips and the second flat-plate-member clip include:
a first clamping plate including an elastic piece that is provided to be elastically deformable and that presses the flat plate member,
a second clamping plate that extends in a predetermined direction and that, together with the first clamping plate, clamps the flat plate member,
a coupling portion that couples together base end sides of the first clamping plate and the second clamping plate in the predetermined direction such that a first facing surface of the first clamping plate and a second facing surface of the second clamping plate face each other while being spaced apart from each other, and
a locking section that is locked to the attachment target member,
the second clamping plate includes a recessed portion that includes a bottom surface that is formed to be recessed from the second facing surface toward a side opposite to a side toward the first facing surface from the second facing surface,
the elastic piece extends from the first facing surface toward the second facing surface while being inclined and extends toward the base end sides from a distal end side opposite to the base end sides in the predetermined direction,
at least a part of a contact portion that is provided at an end portion of the elastic piece on the base end sides and that makes contact with the flat plate member is disposed to enter an inside of the recessed portion,
a distal end of the first clamping plate of the first flat-plate-member clip is disposed at a position substantially the same as a distal end of the second clamping plate of the first flat-plate-member clip in the predetermined direction,
a distal end of the first clamping plate of the second flat-plate-member clip is disposed between a distal end and a base end of the second clamping plate of the second flat-plate-member clip in the predetermined direction, and
the second flat-plate-member clip is disposed between the plurality of first flat-plate-member clips in an extending direction of the flat plate member.
